(19) United States
(12) Patent Application Publication
(10) Pub. No.: US 2006/0245285 A1
(43) Pub. Date: Nov. 2, 2006

(54) METHOD FOR DETECTING THE COMPLETION OF AN OPERATION FOR WRITING A DATA BIT INTO A MEMORY CELL AND CORRESPONDING MEMORY CIRCUIT

(75) Inventors: Franck GENEVAUX, Revel (FR); David Turgis, Letouvet (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics SA, Montrouge (FR)

(21) Appl. No.: 11/381,226

(22) Filed: May 2, 2006

(30) Foreign Application Priority Data
May 2, 2005 (FR) 05 04456

(51) Int. Cl. G11C 7/02

(52) U.S. Cl. 365/210

(57) ABSTRACT

To detect the completion of an operation for writing of a data bit into a memory cell, during the write operation, a data bit written in the memory cell is stored in a dummy memory cell and a change of state of the internal nodes of the dummy memory cell is detected upon the completion of the write operation. The data bit is stored in the dummy memory cell in a storage device that has a lower capacitance relative to the capacitance of the memory cell.

### FIELD OF THE INVENTION

The present invention relates to memory circuits, and, in particular, to the detection of the completion of an operation for writing a data bit into a memory cell.

### BACKGROUND OF THE INVENTION

Memory cells generally take the form of a matrix of memory cells disposed in rows and columns of memory cells and connected in a differential mode between two bit lines. A conventional memory cell is shown in FIG. 1. As can be seen in this figure, the cell C includes two inverters I1 and I2 which store one bit, and two access transistors T1 and T2 via which the cell is connected to two complementary bit lines BLF and BLT, which are used to write a data bit into the memory location or to read it. The input and the output of one of the inverters I1 communicates with the output and input of the other inverter I2, respectively, and form respective data storage nodes N1 and N2 whose voltage levels correspond to the value of a bit stored in the memory.

The two access transistors T1 and T2 are controlled by a word line WL allowing the stored bit to be transferred towards the bit lines BLF and BLT during a read operation or the state of the lines BLF and BLT to be imposed onto the memory location during the write process. In particular, during a write operation of a logic state ‘0’ into one of the data storage nodes, the corresponding bit line, initially precharged to a high logic state, is discharged, whereas the word line WL is positioned at a high level so as to select the corresponding memory locations.

However, the switching time of a memory location from a first logic level towards a second final logic level is non-negligible due to the characteristics of the access transistors T1 and T2. Furthermore, since memory circuits are increasingly sensitive to their external environment, one of the issues for memory circuit manufacturers is to provide protections against all kinds of interference capable of producing a change of state of the memory. Such interference may either consist of a random event known as an SEU (Single Event Upset) which is generated by the impact of an energetic charged particle at a given location in an integrated circuit, or be induced by a point-like capacitive coupling between two layers of the same integrated circuit. In this case, it is referred to as a ‘glitch’.

Protection against these random events often involves the use of a capacitor C1 or C2 which will be added to the overall capacitance of the data storage nodes N1 and N2 and will thus increase the level of charge required to obtain a given voltage level. However, the presence of these capacitors C1 and C2 increases the write time, and so the memory cells are generally associated with a dummy memory cell in which the data bit stored in the main memory cell is stored and which is used to determine the completion of the write operation.

A dummy memory circuit for timing the write operation of a main memory circuit (not shown) is shown in FIG. 2. In this FIG. 2, the dummy memory circuit includes a column of dummy memory cells used to simulate the capacitance of the main memory cells. It will nevertheless be noted that this dummy memory circuit has an identical structure to that of the memory cell with which it is associated to determine the moment at which the word line WL and the bit lines BLT and BLF can be reset to implement a subsequent write operation. It thus comprises a group of dummy memory cells C1, . . . , Cn connected between two bit lines DBLT and DBLF, one of which is optional, and a data write control circuit 10.

A detection circuit 12 is used to detect the time at which the data storage nodes switch from an initial logic level towards a final logic level. This detection circuit 12 comprises two inverters I3 and I4 connected between two data storage nodes N3 and N4 which are themselves connected to the bit lines DBLF and DBLT via access transistors T3 and T4 that are controlled by the same word line WL as that which is used to address the memory cells of the main memory circuit.

This detection circuit 12 operates in the following manner. When a data bit is stored in a memory cell of the main memory circuit, this data bit is simultaneously written into the data storage node N3 by discharging the bit line DBLF under the command of the write control circuit 10. An inverter 14, connected to the other node N4, is used to detect the change of state of this node N4. If such is the case, a reset signal R for the main memory circuit is generated to reset the bit lines and the word line of the main memory cell. Transistors N1 and P1 are then activated to reposition the nodes N3 and N4 in their initial states.

In FIG. 3, a timing diagram illustrating the time behavior of the signals WL, DBLF, N1, N2 and R is shown. As can be seen in this FIG. 3, when the signal WL and the signal DBLF go respectively to the high and low level, the node N3 switches to the low logic level which causes the node N4 to switch to the high logic level. This switching is detected by the inverter I4 which causes the reset signal R to switch, the reset of the main memory cell and the consecutive reset of the signals WL, DBLF, N3 and N4. As can be seen in this figure, the reset of the dummy memory circuit is relatively long due to, in particular, the time T required to reposition the potential of the node N4 in its initial state, because of the presence of the protection capacitors of the memory cells. It is not therefore possible to carry out a subsequent write operation until the reset process has been completed.

### SUMMARY OF THE INVENTION

Accordingly, an object of the invention is to overcome this drawback by providing a memory circuit and a method for detecting the completion of a write operation that allows the drawbacks associated with the presence of the protection capacitors to be overcome.

A first aspect of the invention is a method for detecting the completion of an operation for writing a data bit into a memory cell, including, during the write operation, a data bit written in the the memory cell being stored in a dummy memory cell and a change of state of the internal nodes of the dummy memory cell is detected upon completion of the write operation.

The data bit is stored in the dummy memory cell in a storage device or means that has a lower capacitance relative to the capacitance of the memory cell. In other words, the data bit is stored in a storage device or means with no additional capacitor. It is thus possible to detect the change of state of the data storage nodes and to reset the dummy memory cell without being limited by the presence of such a capacitor.

According to another feature of the invention, the data bit written in the storage cell upon the completion of a preceding write operation is stored in the dummy memory cell and the data bit stored in the dummy memory cell upon the completion of the preceding write operation is compared with the data bit present in the dummy memory cell during the current write operation, the write operation being deemed to be completed as soon as the result of the the comparison reaches a threshold value.

In one embodiment, the dummy memory cell comprises a first data storage node and a second data storage node and inverters interconnected between the first and second storage nodes for the storage of mutually inverted data bits in the nodes, respectively, the data bit written in one of the nodes upon the completion of the preceding write operation is stored and, during the current write operation, the stored data bit is compared with the data bit stored in the other node.

According to yet another feature of the invention, the data bit written upon the completion of the preceding write operation is stored when the addressing word lines of the cell are inactive. Regarding the comparison step, this is performed when the addressing word lines are active. Advantageously, the data bits are written into the dummy memory cell alternately into one and the other data storage nodes.

Another aspect of the invention is a memory circuit comprising an array of memory cells defining data storage nodes associated with a dummy memory circuit used to determine the completion of an operation for writing a data bit into a memory cell. The dummy memory circuit comprises a storage device or means for storing a data bit that is stored in one of the storage cells, wherein the storage means have a lower capacitance than the capacitance of the storage cell.

According to another feature of this circuit, the storage device or means includes a tri-state inverter designed to cause the storage of data in the dummy memory circuit when the addressing word lines of the memory cell array are inactive. According to yet another feature of the memory circuit according to the invention, the dummy memory circuit comprises a first data storage node and a second data storage node, one being used for storing the data bit written in one of the storage cells and the other for storing a data bit written in the storage cell upon the completion of a preceding write operation, and a comparator designed to compare the data respectively stored in the storage nodes. In one embodiment, the dummy memory circuit comprises a write circuit for controlling the storage of the data bit written into one of the storage cells alternately into one and the other data storage node.

### BRIEF DESCRIPTION OF THE DRAWINGS

Other objects, features and advantages of the invention will become apparent upon reading the following description, presented solely as a non-limiting example and with reference to the appended drawings, in which:

FIG. 1 is a schematic diagram illustrating the general structure of a conventional memory cell;

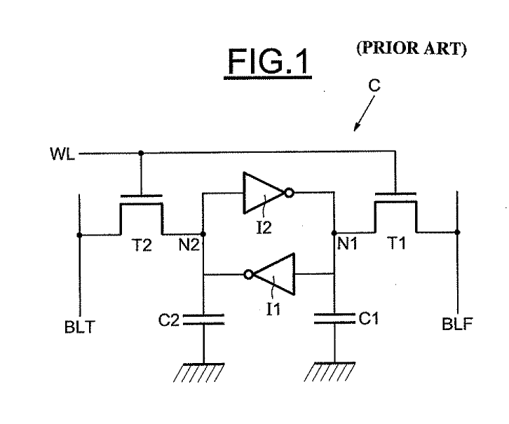

FIG. 2 is a schematic diagram illustrating the general structure of a dummy memory circuit according to the prior art;

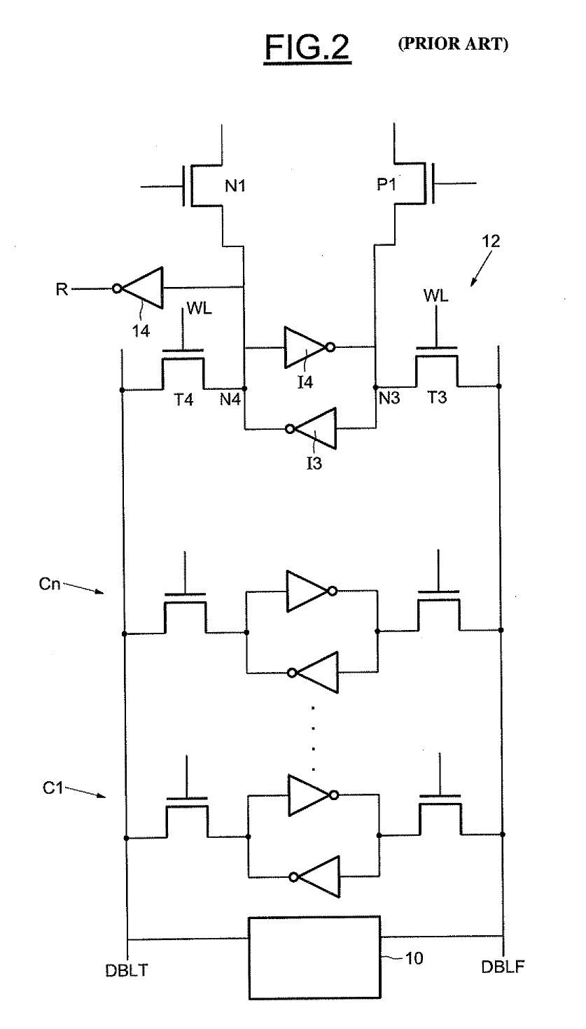

FIG. 3 is a timing diagram illustrating the signals from FIG. 2;

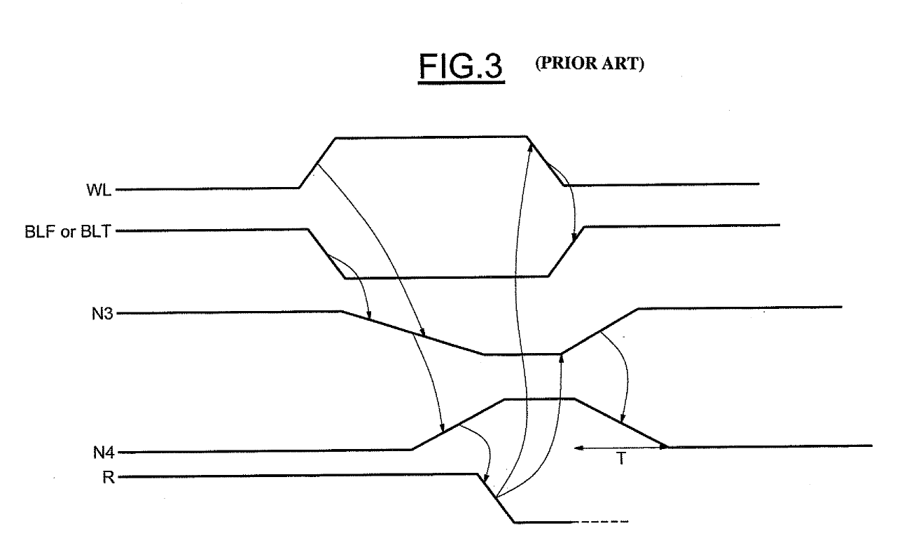

FIG. 4 is a schematic diagram illustrating a dummy memory circuit according to the invention;

FIG. 5 is a timing diagram illustrating the main signals in the dummy memory circuit from FIG. 4; and

FIG. 6 is a schematic diagram illustrating another embodiment of a dummy memory circuit according to the invention.

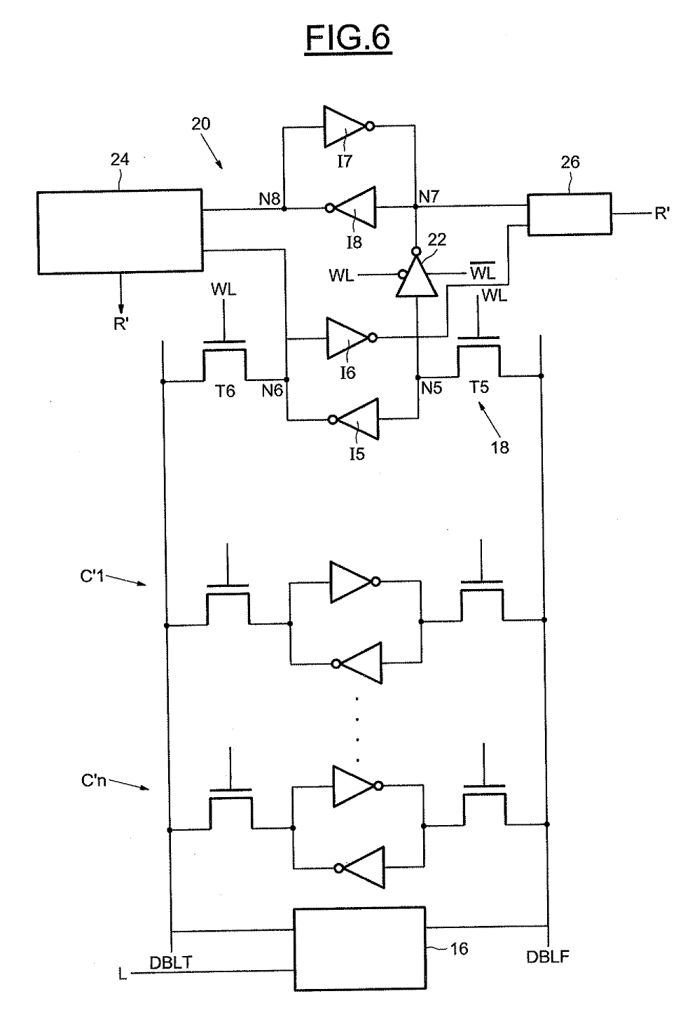

### DETAILED DESCRIPTION OF THE PREFERRED EMBODIMENTS

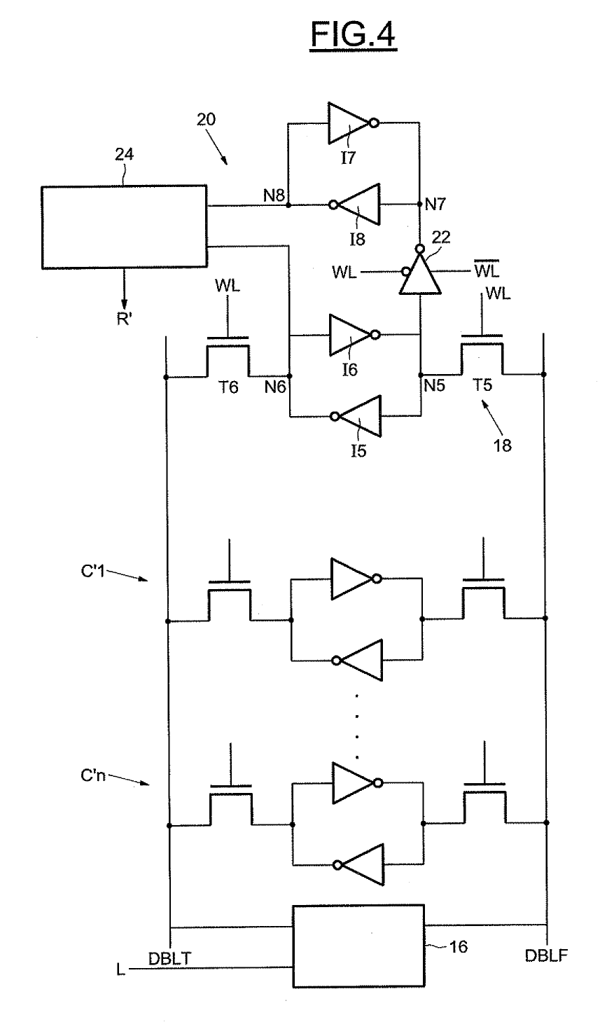

With reference to FIG. 4, the general structure of a dummy memory circuit according to the invention will be described. This dummy memory circuit is designed to be associated with a main memory circuit and has a structure that is substantially identical to the memory circuit with which it is designed to be associated. It is designed to detect the moment at which a main memory write operation is completed to implement a memory reset phase by repositioning the word lines and bit lines in their initial states.

Accordingly, the dummy memory circuit shown in FIG. 4 comprises a group of memory cells C′1, . . . , C′n that are identical to the group of memory cells of the main memory circuit and which are used to simulate the capacitance of these cells. These cells are placed between two bit lines DBLF and DBLT. A write circuit 16 provides the control and timing of a write operation under the control of a locking command signal L.

For detecting the switching of the internal nodes of the dummy memory cells, the circuit shown in FIG. 4 also comprises a detection circuit 18 connected between the bit lines DBLF and DBLT. This detection circuit comprises a dummy memory cell formed by the association of two inverters I5 and I6 connected between two data storage nodes N5 and N6 and two access transistors T5 and T6 connected between a data storage node N5 (and N6, respectively) and a bit line DBLF (and DBLT, respectively).

An additional data storage cell 20 is used to store the data bit stored in one of the nodes, namely the node denoted by the reference N5. This locking cell is formed by the association of two inverters I7 and I8 configured as a flip-flop between two data storage nodes N7 and N8. The storing of the data bit stored in the node N5 in the additional storage cell 20 is carried out by means of a transfer gate 22, whose active or inactive state is controlled by signals WL and \overline{WL} that are respectively formed by the signal present on the word line WL and the other by the complement of this signal. This transfer gate 22 is, for example, formed by a tri-state inverter and is configured so as to cause the transfer of the data bit from the node N5 into the storage cell 20 when the word lines are inactive, in other words between two write phases. Instead of a tri-state inverter, any other logic element could however be used that were suitable for copying the data storage node N5 into the storage cell 20, such as a transmission gate known as ‘passgate’ or an ‘OR’ logic gate.

A comparator 24 is used for comparing the data bit stored in the node N8 of the storage cell 20, at the output of the inverter I8, and the data bit stored in the node N6 of the detection circuit 18, at the output of the inverter I5. A reset signal R′ is generated by the comparator 24 when the result of the comparison exceeds a threshold value meaning that the node N6 has changed state. This signal R′ is generated as soon as the output of the comparator 24 goes high.

As can be seen, the inverters I7 and I8 used to form the storage cell 20 and also the transfer gate 22 have no capacitors, so that the transfer of the data from the node N5 to the node N8, by way of the transfer gate and the inverters I7 and I8, is fast. It will also be noted that, where the transfer of the data from the node N5 towards the storage cell 20 is performed between two write cycles, the data bit stored in the storage cell 20 corresponds to the data bit written into the memory cell during a preceding write cycle.

Thus, the comparison, which is carried out when the word lines are active, in other words during a write phase, includes comparing the data bit stored in the node N6 and the data bit present in the node NS, in other words the data bit stored in the detection circuit 18 with the data bit that was stored there in the course of a preceding write operation. The result of the comparison now allows the completion of the current write operation to be detected by detecting the change of state at the node N6.

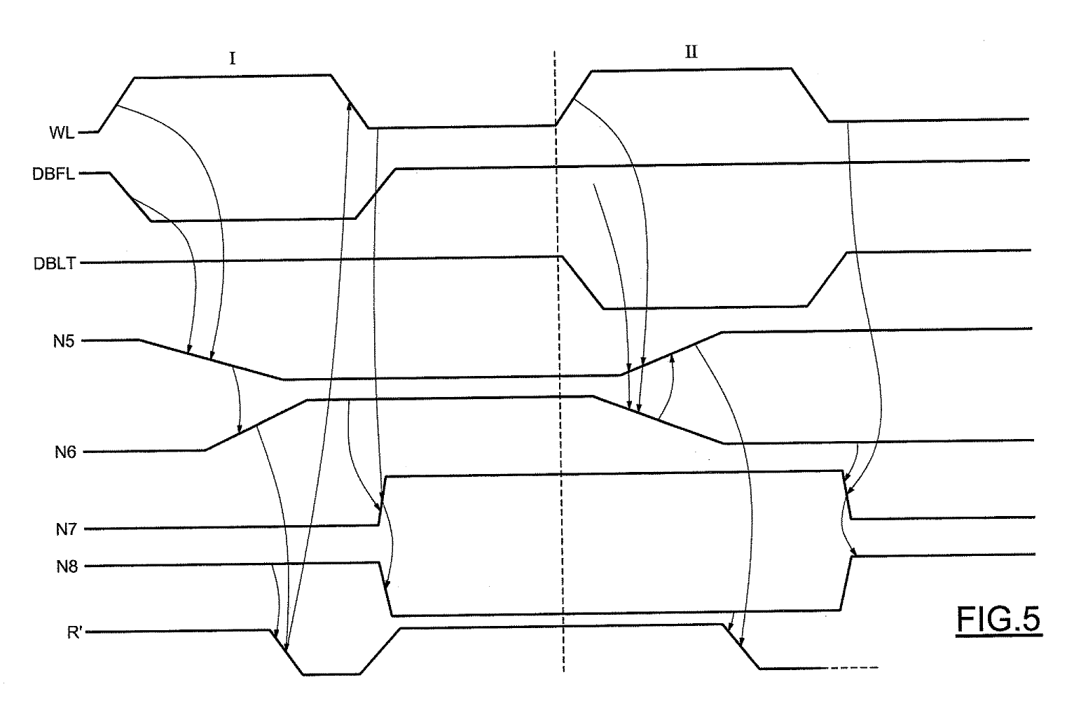

In FIG. 5, a timing diagram is shown that illustrates the time behavior of the signals WL, DBLF, DBLT, N5, N6, N7, N8 and R′ in the course of two consecutive write cycles I and II. As can be seen, the first write cycle I starts by positioning at the high level the word line WL, in other words the word line corresponding to the main memory cell in which a data bit needs to be stored, and by positioning at the low level the bit line DBLF of the dummy memory circuit. This leads to a discharging of the node N5 and a consecutive charging of the node N6. In the course of this first write phase, the result of the comparison carried out by the comparator 24 between the node N6 and the node NS causes a change of state of the reset signal R′ and, at the same time, a repositioning of the signal WL at the low level and a repositioning of the signal DBLF at the high level. The process then continues with the transfer of the data from the nodes N5 and N6 into the nodes N7 and N8, following the completion, thus detected, of the first write cycle I. A further write cycle II can then commence.

It will be noted that, to avoid having to reset the bit lines DBLT and DBLF, the data writing under the control of the write circuit 16 is performed alternately into one and the other of the data storage nodes N5 and N6. It is still possible, however, to only write the data bit into one of the nodes. In this case, the dummy memory circuit will only comprise a single bit line. However, in this case, a reset phase for the bit line used to write the data bit into the data storage node will be provided.

When data is alternately written into one and the other node N5 and N6, during the next write cycle II, the bit line DBLT is activated and is discharged under the control of the write circuit 16, causing the data bit to be stored in the node N6 then a consecutive switching of the node N5. In this case, as shown in FIG. 5, in this embodiment according to which data is alternately written into one and the other data storage node N5 and N6 of the detection circuit 18, two comparators 24 and 26 are used, one to provide a comparison between the data storage nodes N6 and N8 when a data bit is written into one of the nodes N6, and the other a comparison between the data storage nodes N5 and N7 when a data bit is written into the other node N5, to deliver a reset signal R′. A reset of the memory is then carried out as soon as the difference between the nodes N5 and N7, on the one hand, and between the nodes N6 and N5, on the other, exceeds a predetermined threshold value.

1-10. (canceled)

11. A method for detecting completion of a data bit write operation in a memory cell of a memory circuit, the method comprising:
storing, in a dummy memory cell, a data bit written in the memory cell during the write operation, the dummy memory cell including internal nodes and having a lower capacitance relative to the capacitance of the memory cell; and
detecting a change of state of the internal nodes of the dummy memory cell upon completion of the write operation.

12. The method according to claim 11, wherein detecting comprises:
comparing a previous data bit stored in the dummy memory cell upon completion of a preceding write operation with the data bit present in the dummy memory cell during the current write operation; and
determining the write operation to be complete when a comparison result reaches a threshold value.

13. The method according to claims 12, wherein the internal nodes of the dummy memory cell comprise a first data storage node and a second data storage node and inverters connected between the first and second storage nodes for the storage of mutually inverted data bits therein, respectively, and during the current write operation the data bit written in the first storage node from the preceding write operation is compared with the data bit stored in the second data storage node.

14. The method according to claim 13, wherein the memory circuit includes addressing word lines; and the comparing is performed when the addressing word lines are active.

15. The method according to claim 14, wherein the data bit written upon the completion of the preceding write operation is stored when the addressing word lines of the cell are inactive.

16. The method according to claim 15, wherein the data bits are written into the dummy memory cell alternately into the first and second data storage nodes.

17. A memory circuit comprising:
an array of memory cells defining data storage nodes; and
a dummy memory circuit associated with the array for determining completion of a data bit write operation in a memory cell of the array, the dummy memory circuit comprising a storage device for storing a data bit that is written into one of the memory cells, and having a lower capacitance than the capacitance of the memory cell.

18. The memory circuit according to claim 17, wherein the dummy memory circuit comprises:
a first data storage node to store the data bit written in one of the storage cells during a current write operation;
a second data storage node to store a data bit written in the storage cell during a preceding write operation; and
a comparator to compare the respective data bits stored in the storage nodes.

19. The memory circuit according to claim 18, further comprising addressing word lines associated with the memory cell array; and wherein the dummy memory circuit includes a tri-state inverter to cause the storage of data in the dummy memory circuit when the addressing word lines of the memory cell array are inactive.

20. The memory circuit according to claim 19, wherein the dummy memory circuit comprises a write circuit for controlling the storage of data bits written into the dummy memory cell by alternately writing into the first and second data storage nodes.

21. A memory circuit comprising:
an array of memory cells; and
a dummy memory circuit associated with the array and comprising
a dummy memory cell to store a data bit written in a corresponding memory cell during a current write operation, the dummy memory cell including internal nodes and having a lower capacitance relative to the capacitance of the memory cell, and
a detection circuit to detect a change of state of the internal nodes of the dummy memory cell upon completion of the write operation

22. The memory circuit according to claim 21, wherein the internal nodes of the dummy memory circuit comprise a first data storage node to store the data bit written in one of the storage cells during a current write operation, and a second data storage node to store a data bit written in the storage cell during a preceding write operation; and the dummy memory circuit further comprising a comparator to compare the respective data bits stored in the storage nodes.

23. The memory circuit according to claim 22, further comprising addressing word lines associated with the memory cell array; and wherein the dummy memory circuit includes a tri-state inverter to cause the storage of data in the dummy memory circuit when the addressing word lines of the memory cell array are inactive.

24. The memory circuit according to claim 23, wherein the dummy memory circuit comprises a write circuit for controlling the storage of data bits written into the dummy memory cell by alternately writing into the first and second data storage nodes.
